(19) United States
(12) Patent Application Publication
(10) Pub. No.: US 2014/0090150 A1
(43) Pub. Date: Apr. 3, 2014

(54) METHOD AND PROCESS OF USING THERMAL-ELECTRONICS AS PART OF A GARMENT TO CREATE AN ELECTRICAL DISTRIBUTED CHARGE

(71) Applicant: Anzen Electronics, LLC, Carmel, IN (US)

(72) Inventor: Richard J. Skertic, Carmel, IN (US)

(73) Assignee: Anzen Electronics, LLC, Carmel, IN (US)

(21) Appl. No.: 14/041,207

(22) Filed: Sep. 30, 2013

Related U.S. Application Data
(60) Provisional application No. 61/709,035, filed on Oct. 2, 2012.

(51) Int. Cl. A41D 1/00; H01L 35/34; H01L 35/32

(52) U.S. Cl. CPC A41D 1/002; H01L 35/325; H01L 35/34
USPC 2/243.1; 136/225; 136/201

(57) ABSTRACT

A thermal-electronic device includes a first thermo-electric material having a first charge and a second thermo-electronic material having a second charge that is opposite the first charge. A flexible conductive interconnection is positioned between the first thermo-electric material and the second thermo-electric material to bond the first thermo-electric material and the second thermo-electric material into a segment. A plurality of segments are bonded together to form a thread having alternating first thermo-electric materials and second thermo-electric materials. The conductive interconnection allows a charge to flow between the first thermo-electric materials and second thermo-electric materials.

### CROSS-REFERENCE TO RELATED APPLICATIONS

This application is a non-provisional application of U.S. patent application Ser. No. 61/709,035 filed Oct. 2, 2012 and titled “A METHOD AND PROCESS OF USING THERMAL-ELECTRONICS AS PART OF A GARMENT TO CREATE AN ELECTRICAL DISTRIBUTED CHARGE”, which is herein incorporated by reference in its entirety.

### TECHNICAL FIELD OF THE DISCLOSURE

The present disclosure generally relates to a thermal-electronic device and a method of manufacturing such a device; and particularly, to a thermal-electronic device with high density and efficiency, along with the construction of such a device to form a flexible “ribbon” such that a plurality of ribbons can be incorporated into a garment and connected to a distributed charging management system.

### BACKGROUND OF THE DISCLOSURE

Thermo-electric thin film methods have been used to form high-performance thermo-electronic devices for many years. Thermo-electric materials have been structured into such configurations as super-lattice, quantum-well and quantum-dot. However, there still exists a need to produce a thermo-electric component structure with a better aspect ratio. There is also a need to easily interconnect these components in such a way as to optimize energy extraction such that the components can be incorporated into a garment to charge or power wearable, mobile or fixed electronic devices. The methods used to manufacture the devices must be amenable to automation, compatible with cascading or multi-staging (leading to a smaller components for a higher coefficient of performance in a refrigerator or for higher efficiency in a power generator), and equally applicable to both cooling and power generation.

### SUMMARY OF THE DISCLOSURE

A method or process of creating an electrical charge given a heat gradient source, thermal amplifying material (for example only, highly oriented pyrolytic graphite), and thermal-electronic elements constructed in such a way that it can be incorporated into garments either on the garment or within the garment. The electrical charge created by the device can be used to charge or power devices that are wearable, mobile or stationary.

In one embodiment, a thermal-electronic device includes a first thermo-electric material having a first charge and a second thermo-electronic material having a second charge that is opposite the first charge. A flexible conductive interconnection is positioned between the first thermo-electric material and the second thermo-electric material to bond the first thermo-electric material and the second thermo-electric material into a segment. A plurality of segments are bonded together to form a thread having alternating first thermo-electric materials and second thermo-electric materials. The conductive interconnection allows a charge to flow between the first thermo-electric materials and second thermo-electric materials.

In one embodiment, a garment configured to generate power from body heat includes a thermal-electronic device integrated with the garment. The thermal-electronic device includes a first thermo-electric material having a first charge and a second thermo-electronic material having a second charge that is opposite the first charge. A flexible conductive interconnection is positioned between the first thermo-electric material and the second thermo-electric material to bond the first thermo-electric material and the second thermo-electric material into a segment. A plurality of segments are bonded together to form a thread having alternating first thermo-electric materials and second thermo-electric materials. The conductive interconnection allows a charge to flow between the first thermo-electric materials and second thermo-electric materials.

In one embodiment, a method of forming a thermal-electronic device includes coupling a first thermo-electric material having a first charge and a second thermo-electronic material having a second charge that is opposite the first charge. A flexible conductive interconnection is positioned between the first thermo-electric material and the second thermo-electric material to bond the first thermo-electric material and the second thermo-electric material into a segment. A plurality of segments are bonded together to form a thread having alternating first thermo-electric materials and second thermo-electric materials, wherein the conductive interconnection allows a charge to flow between the first thermo-electric materials and second thermo-electric materials.

Other embodiments are also disclosed.

### BRIEF DESCRIPTION OF THE DRAWINGS

The embodiments and other features, advantages and disclosures contained herein, and the manner of attaining them, will become apparent and the present disclosure will be better understood by reference to the following description of various exemplary embodiments of the present disclosure taken in conjunction with the accompanying drawings, wherein:

FIG. 1a is schematic view of negative charge materials and positive charge materials.

FIG. 1b is a schematic view of a negative charge material and a positive charge material joined by a conductive interconnection.

FIG. 2 is a schematic view of a chain of negative charge materials and positive charge materials joined by conductive interconnections.

FIG. 3 is a schematic view of an insulating material.

FIG. 4 is a schematic view of a thermal-electronic device formed in accordance with an embodiment.

FIG. 5 is a schematic view of a heat gradient over the thermal-electronic device shown in FIG. 4.

FIG. 6 is a perspective cross-sectional schematic view of a heat gradient over the thermal-electronic device shown in FIG. 4.

FIG. 7 is a schematic view of a plurality of thermal-electronic devices woven together in accordance with an embodiment.

FIG. 8a illustrates a position of the thermal-electronic device in a garment in accordance with an embodiment.

FIG. 8b illustrates a position of a charge/power distribution management system in a garment in accordance with an embodiment.

### DETAILED DESCRIPTION OF THE DISCLOSED EMBODIMENTS

For the purposes of promoting an understanding of the principles of the disclosure, reference will now be made to the embodiments illustrated in the drawings and specific language will be used to describe the same. It will nevertheless be understood that no limitation of the scope of the disclosure is thereby intended, and alterations and modifications in the illustrated systems, and further applications of the principles of the disclosure as illustrated therein are herein contemplated as would normally occur to one skilled in the art to which the disclosure relates.

In certain embodiments, a thermal-electronic device to provide an electrical charge given a heat gradient source, thermal amplifying material (for example, a highly oriented pyrolytic graphite), and thermal-electronic elements is provided. A method for forming the thermal-electronic device is also provided. The thermal-electronic device is constructed in such a way that it can be incorporated into garments either on the garment or within the garment. The electrical charge created by such the thermal-electronic device can be used to charge or power devices that are wearable, mobile or stationary.

Most non-fossil fuel electricity generation devices depend on local natural resources to create electricity and they all have their limitations. For example, wind depends on air movement. If there is no air movement then the generation of electricity will not happen. Solar power is limited to daytime generation with storage batteries for usage at night and on cloudy days. This limitation is compounded because a typical mobile solar power source is limited to approximately 60 watts or even less for a small (10 watts) portable system. Thermal systems require a thermal gradient in order to generate power but those conditions are geographically unique and limited to certain areas in the world and are time consuming to setup. Most require a lot of equipment and are not portable.

However, thermal-electronic devices are portable and can generate at least approximately 100 watts or more of power depending on the heat source gradient. The source of this heat gradient is living creatures and specifically, the human body, to generate power.

The human body when at rest requires on average about 2250 Kcal/day, and depending on the metabolism, the body is only about 90% efficient which means it burns 2020 Kcal/day. Converting this to watts yields (0.253 Kcal=1 BTU) giving 8000 BTU/day or 333.34 BTU/hr which is 97.67 watts. If a person were to exert themselves this would be even higher. So at a minimum the human body generates approximately 100 watts of power. Thermal-electronics harnesses this power and converts it to energy that can be used to charge or power other devices.

A thermal-electronic device is built in layers that create a “ribbon” like or “thread” like structure that can be stitched into or placed on the inside of tight fitting garments such that the device is in contact with the wearer. The threads are placed in the garments where heat is generated even at rest. For example, the device may be placed along the sides of a wearer, under the arms along the ribs or on the inner side of the thighs. The thermal-electronic device can even be located in a hat or helmet since the majority of heat lost from the human body is through the head. The device includes flexible joints with alternating junctions exposed on opposite sides of the thread. This produces a Seebeck effect, which is the conversion of temperature differences (thermal gradient across the device) directly into an electrical charge.

Charges in the device's inner material will diffuse when one side of a conductor is at a different temperature from the other. Thus a thermal gradient must exist in order for an electric charge to exist. Charge flows through a negative charge material, or n-type material element, crosses a flexible metallic interconnection, and passes into a positive charge material, or p-type material element. An outer thermal amplifying material (for example, highly oriented pyrolytic graphite) acts as an amplifier to assist in the development of the heat gradient across the device. In an alternative embodiment, if a power source is provided, the thermo-electric device may act as a cooler by the Peltier effect.

Placing the thermal-electronic device into or affixed it to the inside of a tight fitting garment could cause a heat gradient across the device that is the result of heat generated off the human body and dissipating into the air. This causes an electrical charge or current to be generated in the device that can be regulated to trickle charge a centralized plate battery or other multiplicity of batteries types as required. Thus, the human body is the power source for the battery charge.

Referring to the drawings, wherein like reference numerals designate corresponding elements throughout the several views, a thermal-electronic device is provided. The device, according to one embodiment, includes an n-type material 11 and p-type material 10, as shown in FIG. 1a. The n-type material and the p-type material may be developed from a process for forming crystalline wafers using the Czochralski process. In this process, a cylindrical ingot of high purity mono-crystalline semiconductor, such as silicon or germanium, is formed by pulling a seed crystal from a “melt”. Donor impurity atoms, such as boron or phosphorus in the case of silicon, can be added to the molten intrinsic material in precise amounts in order to dope the crystal, thus changing it into n-type or p-type extrinsic semiconductor. Once cut and polished, typical dimensions of these segments could be anywhere from approximately 2.3 mm by approximately 2.3 mm (width by length) to approximately 4.7 mm by approximately 4.7 mm, but other sizes are possible. The thickness can range from approximately 0.275 mm to approximately 0.975 mm. The n-type material 11 and p-type material 10 are metalized and their respective surfaces providing a low-resistance contact, such as a low resistance Peltier contact, are joined, as shown in FIG. 1b using a conductive interconnection 14. The n-type and p-type materials are bonded together to form a segment 12. The bonding may be carried out using a conventional bonding method. This bond can create a solid structure or the material can be joined together using a stent like zigzag pattern with every third peak connected to the previous or next row in a tubular structure to allow for a certain degree of flexibility.

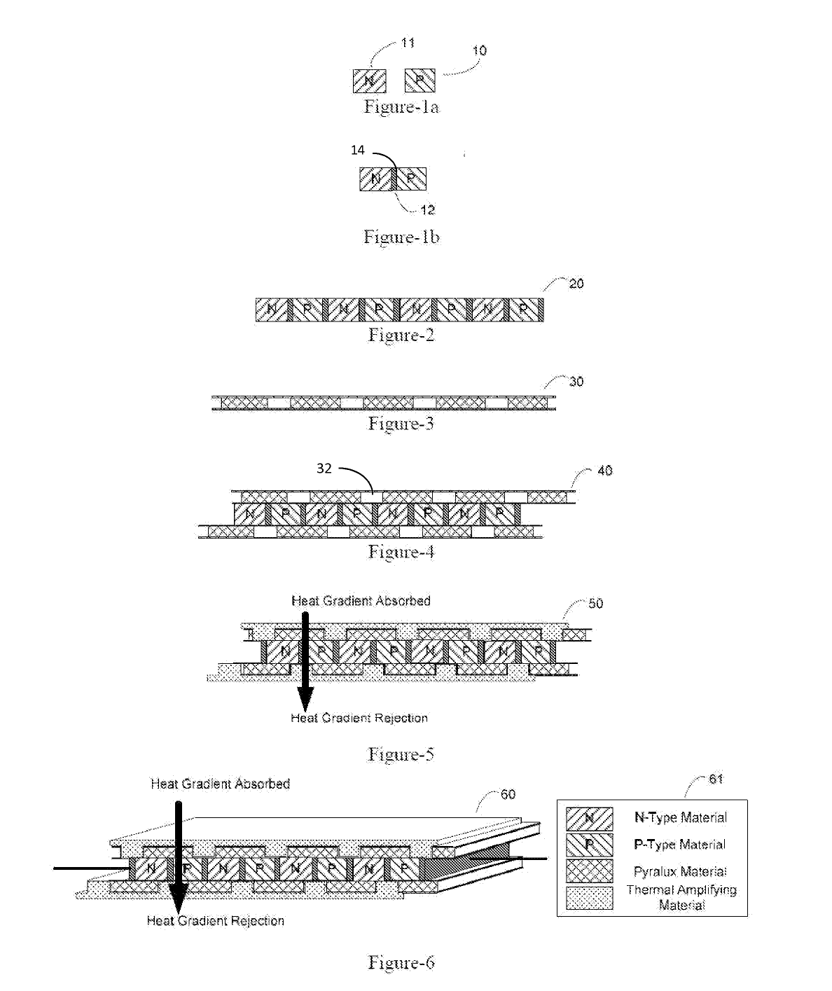

The bonding sequence of the segments will alternate material type as shown in FIG. 2 to produce a chain or ribbon 20 of n-p-n-p- . . . type material. During this bonding of n-type material and p-type material into a chain, a Pyralux flexible circuit material 30 or the like (shown in FIG. 3) is applied with an epoxy adhesive or the like to both the top and bottom (offset from each other by one junction) to form a sandwich encasing the n-p type material as shown in FIG. 4 and complete the thermal-electronic device 40. The Pyralux flexible circuit material 30 includes windows 32 punched out of it to expose the junctions, i.e. conductive interconnections 14, between the bonded n-p type segments. The windows 32 expose the conductive interconnections 14 between the different materials in the segments. When heating the conductive interconnections 14 between material types and cooling the other ends of the segment, or the adjacent conductive interconnection 14, negatively and positively charged partials move freely through the thermal-electronic device. The mobile positively charged partials in the p-type material are excited by the heat and move further into the segment with the extra kinetic energy. The same happens to the mobile electrons in the n-type material. The net effect is that many of the positive charges pile up at the cold end of the p-type element and many of the negative charges (electrons) pile up at the cold end of the n-type element, thereby creating a voltage potential across the conductive interconnections 14 when measured from cold end to cold end. By placing an electrical load across the ends, a circuit is formed, allowing current flow across a voltage potential (from the p-n junction), and electrical power is created. This power is a function of many things such as temperature difference, Seebeck coefficients, and the electrical load that connects the cold sides. In one embodiment, the thermal-electronic device 40 is extrapolated for many n-p couples to allow for a denser power ratio and power to junction. The Pyralux flexible circuit material 30 gives the thermal-electronic device 40 a more stable structure and allows for handling.

To achieve a uniform thermally conductive surface, the assembly shown in FIG. 4 may be coated on the top and bottom with a highly oriented pyrolytic graphite sheet 50, as shown in FIG. 5. This flexible material will fill the gaps in the punched out Pyralux material to complete the assembly of the thread 60, as shown in FIG. 6.

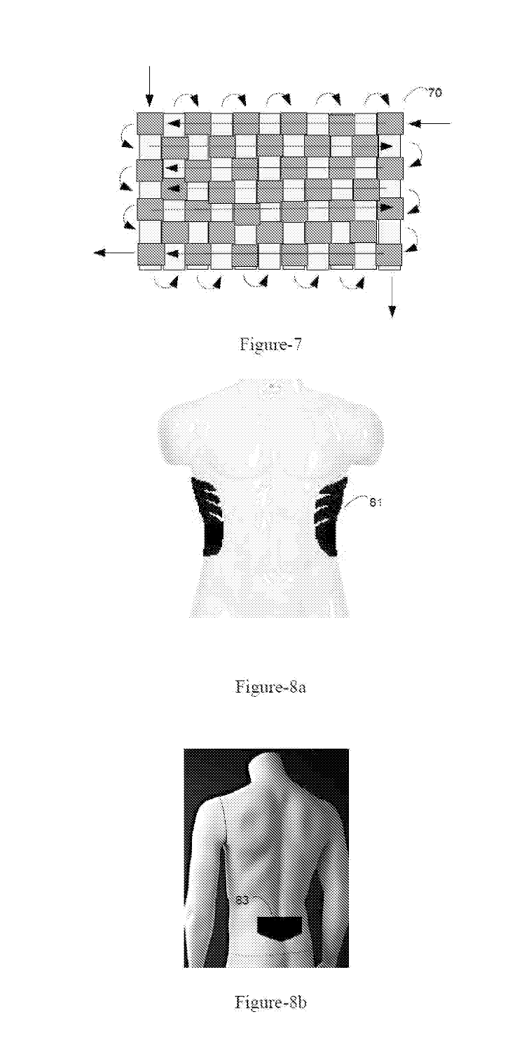

With the thread 60 constructed, a thermal patch 70 or entire garment can be woven to increase the density of the thermal elements. An example of a weave is shown in FIG. 7. There are many different ways to weave the thermal patch 70 to incorporate the thermo-electronic device. The ends of the patchworks continue to the next row and next column feeding a distributing charging/power management system 83 that could include a rechargeable battery. The location of this thermal patch 70 will be incorporated into tight fitting garments to be worn against the body. FIG. 8a shows one of many ideal locations 81, but there are other locations that will work such as down the middle of the back or between the legs on the inner thigh or back of the knees. The thermal patchwork can fit comfortably under the arm and down the side with “fingers” wrapping the chest allowing for movement by the user. FIG. 8b shows one ideal placement on the lower back, but there are other locations as well, for the charging/power distribution management system 83, that could include a rechargeable battery.

What is claimed is:

1. A thermal-electronic device comprising:
a first thermo-electric material having a first charge;
a second thermo-electronic material having a second charge that is opposite the first charge; and
a flexible conductive interconnection positioned between the first thermo-electric material and the second thermo-electric material to bond the first thermo-electric material and the second thermo-electric material into a segment, wherein a plurality of segments are bonded together to form a thread having alternating first thermo-electric materials and second thermo-electric materials, and wherein the conductive interconnection allows a charge to flow between the first thermo-electric materials and second thermo-electric materials.

2. The thermal-electronic device of claim 1, further comprising a strip of flexible graphite adhered to at least one of a top or a bottom of the thread.

3. The thermal-electronic device of claim 1, wherein a heat gradient across the conductive interconnection facilitates the charge flowing between the first thermo-electric materials and second thermo-electric materials.

4. The thermal-electronic device of claim 3, wherein a direction of the charge is dependent on a direction of the heat gradient.

5. The thermal-electronic device of claim 3, wherein the heat gradient is formed from body heat.

6. The thermal-electronic device of claim 1 further comprising a plurality of threads woven together to form a fabric.

7. The thermal-electronic device of claim 1, wherein the fabric is integrated with a garment.

8. The thermal-electronic device of claim 7, wherein the fabric is integrated into a portion of the garment that corresponds to a body part of a garment wearer that generates heat.

9. The thermal-electronic device of claim 6, wherein the fabric is formed into a garment.

10. The thermal-electronic device of claim 6, wherein the fabric is configured to couple to and charge a power distribution system.

11. The thermal-electronic device of claim 1 further comprising an insulating material encasing the thread.

12. The thermal-electronic device of claim 11 further comprising windows formed in the insulating material, the windows aligned with conductive interconnections to enable a heat gradient to pass through.

13. The thermal-electronic device of claim 12, wherein the windows are formed on at least one of a top of the thread or a bottom of the thread.

14. The thermal-electronic device of claim 1 further comprising a power distribution system electrically coupled to the thread.

15. A garment configured to generate power from body heat, the garment comprising:
a thermal-electronic device integrated with the garment, the thermal-electronic device comprising:
a first thermo-electric material having a first charge;
a second thermo-electronic material having a second charge that is opposite the first charge; and
a flexible conductive interconnection positioned between the first thermo-electric material and the second thermo-electric material to bond the first thermo-electric material and the second thermo-electric material into a segment, wherein a plurality of segments are bonded together to form a thread having alternating first thermo-electric materials and second thermo-electric materials, and wherein the conductive interconnection allows a charge to flow between the first thermo-electric materials and second thermo-electric materials.

16. A method of forming a thermal-electronic device comprising:
coupling a first thermo-electric material having a first charge and a second thermo-electronic material having a second charge that is opposite the first charge; and
positioning a flexible conductive interconnection between the first thermo-electric material and the second thermo-electric material to bond the first thermo-electric material and the second thermo-electric material into a segment; and
bonding a plurality of segments together to form a thread having alternating first thermo-electric materials and second thermo-electric materials, wherein the conductive interconnection allows a charge to flow between the first thermo-electric materials and second thermo-electric materials.

17. The method of claim 16 further comprising creating a charge between the first thermo-electric materials and second thermo-electric materials with a heat gradient.

18. The method of claim 17 further comprising creating the charge with a heat gradient formed from body heat.

19. The method of claim 16 further comprising integrating the thread with a garment.

20. The method of claim 16 further comprising weaving a plurality of threads together to form a fabric.

21. The method of claim 16 further comprising integrating the fabric with a garment.

22. The thermal-electronic device of claim 21 further comprising integrating the fabric into a portion of the garment that corresponds to a body part of a garment wearer that generates heat.

23. The thermal-electronic device of claim 20 further comprising forming the fabric into a garment.

24. The thermal-electronic device of claim 20 further comprising:
coupling the fabric to a power distribution system; and
charging the power distribution system with the fabric.

25. The method of claim 16 further comprising encasing the thread with an insulating material.

26. The method of claim 25 further comprising forming windows in the insulating material, the windows aligned with conductive interconnections to enable a heat gradient to pass through.

27. The method of claim 26 further comprising forming the windows on at least one of a top or a bottom of the thread.

28. The method of claim 16 further comprising electrically coupling a power distribution system to the thread.
